(19) United States
(12) Patent Application Publication
(10) Pub. No.: US 2025/0381612 A1
(43) Pub. Date: Dec. 18, 2025

(54) LASER PROCESSING SYSTEM AND ELECTRONIC DEVICE MANUFACTURING METHOD

(71) Applicant: GIGAPHOTON INC., Tochigi (JP)

(72) Inventor: Yousuke FUJIMAKI, Tochigi (JP)

(73) Assignee: GIGAPHOTON INC., Tochigi (JP)

(21) Appl. No.: 19/197,951

(22) Filed: May 2, 2025

(30) Foreign Application Priority Data
Jun. 13, 2024 (JP) 2024-096189

(51) Int. Cl. B23K 26/06; H01L 21/48

(52) U.S. Cl. CPC B23K 26/0608; H01L 21/4846

(57) ABSTRACT

A laser processing system according to an aspect of the present disclosure includes a laser apparatus configured to output a laser beam having two or more spatial modes; a splitting optical element disposed in an optical path of the laser beam and configured to split the laser beam into multiple split beams each having the spatial modes with the number thereof reduced; and at least one dividing diffractive optical element configured to divide each of the multiple split beams into multiple divided beams at a surface of a workpiece.

### CROSS-REFERENCE TO RELATED APPLICATIONS

The present application claims the benefit of Japanese Patent Application No. 2024-096189, filed on Jun. 13, 2024, the entire contents of which are hereby incorporated by reference.

### BACKGROUND

### 1. Technical Field

The present disclosure relates to a laser processing system and an electronic device manufacturing method.

### 2. Related Art

In recent years, a semiconductor exposure apparatus is required to improve the resolution thereof as semiconductor integrated circuits are increasingly miniaturized and highly integrated. To this end, reduction in the wavelength of light emitted from a light source for exposure is underway. For example, a KrF excimer laser apparatus, which outputs a laser beam having a wavelength of about 248.4 nm, and an ArF excimer laser apparatus, which outputs a laser beam having a wavelength of about 193.4 nm, are used as a gas laser apparatus for exposure.

An excimer laser beam, which has a pulse width of about several tens of nanoseconds and has a short wavelength, is used in some cases to directly process a polymer material, a glass material, and other materials.

The excimer laser beam having photon energy higher than chemical binding energy of a polymer material can unbind a chemical bond in the polymer material. Non-thermal processing can therefore be performed on the polymer material by using the excimer laser beam, and it is known that an excellent processed shape is achieved by the non-thermal processing.

Glass, ceramic, and other materials absorb the excimer laser beam by a large amount, and it is therefore known that the excimer laser beam can process a material difficult to process with a visible or infrared laser beam.

### CITATION LIST

### Patent Literature

[PTL 1] U.S. Patent application Publication No. 2020/070280

### SUMMARY

A laser processing system according to an aspect of the present disclosure includes a laser apparatus configured to output a laser beam having two or more spatial modes; a splitting optical element disposed in an optical path of the laser beam and configured to split the laser beam into multiple split beams each having the spatial modes with the number thereof reduced; and at least one dividing diffractive optical element configured to divide each of the multiple split beams into multiple divided beams at a surface of a workpiece.

An electronic device manufacturing method according to another aspect of the present disclosure includes producing an interposer by performing laser processing on an interposer substrate by using a laser processing system; coupling the interposer and an integrated circuit chip to each other to electrically connect the interposer and the integrated circuit chip to each other; and coupling the interposer and a circuit substrate to each other to electrically connect the interposer and the circuit substrate to each other, the laser processing system including a laser apparatus configured to output a laser beam having two or more spatial modes, a splitting optical element disposed in an optical path of the laser beam and configured to split the laser beam into multiple split beams each having the spatial modes with the number thereof reduced, and at least one dividing diffractive optical element configured to divide each of the multiple split beams into multiple divided beams at a surface of a workpiece.

### BRIEF DESCRIPTION OF DRAWINGS

Embodiments of the present disclosure will be described below only by way of example with reference to the accompanying drawings.

FIG. 1 schematically shows the configuration of a laser processing system according to Comparative Example.

FIG. 2 schematically shows the configuration of a laser apparatus.

FIG. 3 shows an example of an element that constitutes a DOE.

FIG. 4 shows an example of the DOE.

FIG. 5 shows multiple laser beams into which an original laser beam is divided by the DOE.

FIG. 6 shows an example in which a beam splitter is used to increase the number of focused spots.

FIG. 7 schematically shows the configuration of a laser processing system according to a first embodiment.

FIG. 8 schematically shows the configuration of a laser processing system according to a second embodiment.

FIG. 9 shows an example of the configuration of a focusing element array.

FIG. 10 shows a result of a simulation performed on the focused spots formed in the second embodiment.

FIG. 11 shows a result of the simulation performed on the focused spots formed in Comparative Example.

FIG. 12 shows a variation of the focusing element array.

FIG. 13 schematically shows the configuration of a laser processing system according to a third embodiment.

FIG. 14 shows light deflected by a prism.

FIG. 15 shows light deflected by a DOE.

FIG. 16 diagrammatically shows the configuration of an electronic device.

FIG. 17 is a flowchart showing an electronic device manufacturing method.

### DETAILED DESCRIPTION

### Contents

1. Comparative Example
1.1 Configuration
1.2 Operation
1.3 Diffractive optical element
1.4 Problems
2. First Embodiment
2.1 Configuration
2.2 Operation
2.3 Advantages
3. Second Embodiment
3.1 Configuration
3.2 Operation
3.3 Advantages
3.4 Simulation
3.5 Variations
4. Third Embodiment
4.1 Configuration
4.2 Operation
4.3 Advantages
5. Electronic device manufacturing method

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same elements have the same reference characters, and no redundant description of the same elements will be made.

### 1. Comparative Example

### 1.1 Configuration

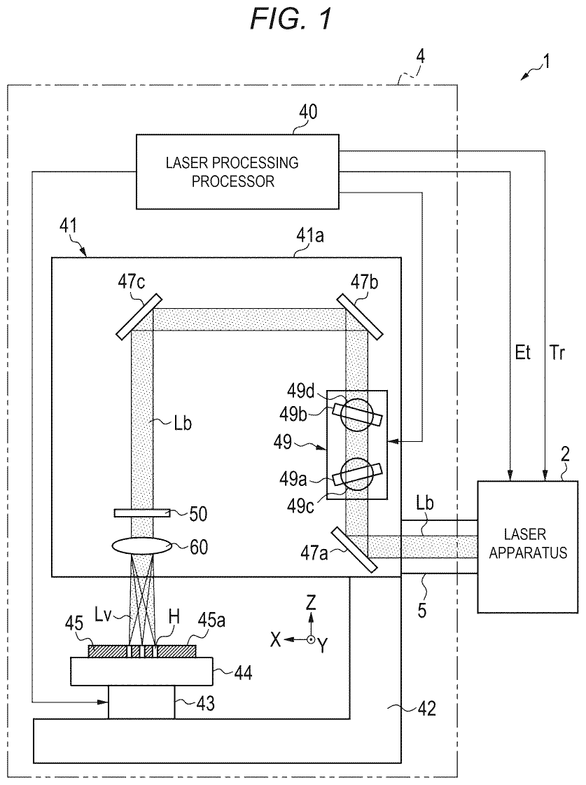

FIG. 1 schematically shows the configuration of a laser processing system 1 according to Comparative Example. Note that Comparative Example is a form that the applicant is aware of as known only by the applicant, and is not a publicly known example that the applicant is self-aware of.

The laser processing system 1 includes a laser apparatus 2 and a laser processing apparatus 4 as primary configurations. The laser processing system 1 is used to perform drilling operation of forming holes such as via holes in a glass substrate for an interposer.

The laser apparatus 2 is a laser apparatus that outputs an ultraviolet pulse laser beam. For example, the laser apparatus 2 is a discharge-excitation-type laser apparatus containing F₂, ArF, KrF, XeCl, or XeF as a laser medium and outputting an ultraviolet pulse laser beam. In the present disclosure, the laser apparatus 2 is a KrF excimer laser apparatus that outputs an ultraviolet pulsed laser beam having a center wavelength of 248.4 nm. The ultraviolet pulse laser beam output by the laser apparatus 2 is hereinafter simply referred to as a laser beam Lb.

The laser apparatus 2 and the laser processing apparatus 4 are connected to each other via an optical path tube 5. The optical path tube 5 is disposed in the optical path of the laser beam Lb between a light exiting port of the laser apparatus 2 and a light incident port of the laser processing apparatus 4.

The laser processing apparatus 4 includes a laser processing processor 40, an optical apparatus 41, a frame 42, an XYZ stage 43, and a table 44. The optical apparatus 41 and the XYZ stage 43 are fixed to the frame 42.

The table 44 supports a workpiece 45. The workpiece 45 is a processing target to be drilled. The workpiece 45 is a glass substrate for an interposer, and is, for example, an alkali-free glass substrate. Note that the workpiece 45 may instead be a substrate made of quartz glass, an organic material, silicon single crystal, or a ceramic material. Multiple holes H are formed in the workpiece 45 through what is called multi-point drilling.

The XYZ stage 43 supports the table 44. The workpiece 45 is fixed onto the table 44. The XYZ stage 43 allows the table 44 to move in the X, Y, and Z directions, and moves the table 44 to change the position of the workpiece 45. The X, Y, and Z directions are perpendicular to each other. The X and Y directions are parallel to a surface 45a of the workpiece 45. The Z direction is perpendicular to the surface 45a. The XYZ stage 43 is a moving stage that allows the workpiece 45 to move in the directions perpendicular to an optical axis of a focusing lens 60.

The optical apparatus 41 includes an enclosure 41a, highly reflective mirrors 47a, 47b, and 47c, an attenuator 49, a diffractive optical element (DOE) 50, and the focusing lens 60. The constituent members in the optical apparatus 41 are fixed to respective holders that are not shown, and disposed at predetermined positions in the enclosure 41a.

The highly reflective mirror 47a is disposed so as to reflect the laser beam Lb having passed through the optical path tube 5, and cause the reflected laser beam Lb to pass through the attenuator 49 and be incident on the highly reflective mirror 47b. The optical path tube 5 and the enclosure 41a are purged, for example, with a purge gas. The purge gas is, for example, a nitrogen gas or an inert gas, and is a gas that hardly absorbs the laser beam Lb.

The attenuator 49 is disposed in the optical path between the highly reflective mirror 47a and the highly reflective mirror 47b in the enclosure 41a. The attenuator 49 includes, for example, two partially reflective mirrors 49a and 49b, and rotary stages 49c and 49d for the partially reflective mirrors 49a and 49b. The partially reflective mirrors 49a and 49b are optical elements having transmittance that changes in accordance with the angle of incidence of the laser beam Lb. The angle of incidence of the laser beam Lb to be incident on the partially reflective mirrors 49a and 49b is adjusted by the rotary stages 49c and 49d, respectively.

The highly reflective mirrors 47b and 47c are disposed so as to reflect the laser beam Lb having passed through the attenuator 49, and cause the reflected laser beam Lb to enter the DOE 50.

The DOE 50 is disposed in the optical path of the laser beam Lb reflected off the highly reflective mirror 47c. The DOE 50 diffracts the laser beam Lb incident from the highly reflective mirror 47c to divide the laser beam Lb into multiple laser beams Lv, which exit at different angles. That is, the DOE 50 divides the laser beam Lb into multiple laser beams spread in the X and Y directions. Note in the present disclosure that “dividing” an incident laser beam means dividing the laser beam into multiple laser beams each having the unreduced number of spatial modes.

The focusing lens 60 is so disposed that the multiple laser beams Lv output from the DOE 50 enter the focusing lens 60 and the focal plane thereof coincides with the surface 45a of the workpiece 45. The focusing lens 60 is, for example, an Fθ lens, and focuses the multiple laser beams Lv output from the DOE 50 to generate a multi-point pattern in which multiple focused spots are arranged in the form of a lattice.

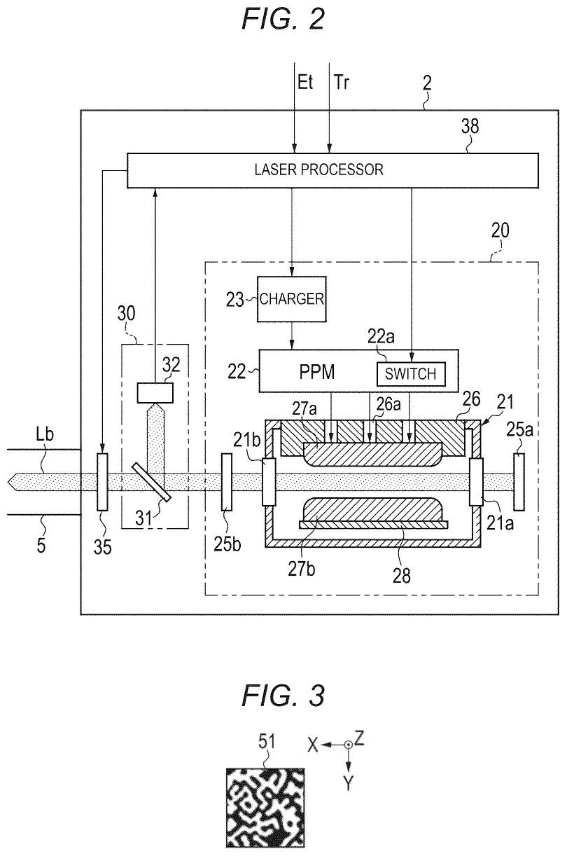

FIG. 2 schematically shows the configuration of the laser apparatus 2. The laser apparatus 2 includes an oscillator 20, a monitor module 30, a shutter 35, and a laser processor 38. The oscillator 20 includes a chamber 21, an optical resonator configured with a rear mirror 25a and an output coupling mirror 25b, a charger 23, and a pulsed power module (PPM) 22.

The chamber 21 is provided with windows 21a and 21b. A laser gas has been encapsulated as the laser medium in the chamber 21.

The chamber 21 has an opening formed therein, and is provided with an electrically insulating plate 26, in which multiple feedthroughs 26a are embedded, so as to close the opening. The PPM 22 is disposed above the electrically insulating plate 26. A pair of discharge electrodes 27a and 27b as primary electrodes and a ground plate 28 are disposed in the chamber 21. A discharge surface of each of the discharge electrodes 27a and 27b has a rectangular shape.

The discharge electrodes 27a and 27b are so disposed that the discharge surfaces thereof face each other to excite the laser medium through discharge. The surface of the discharge electrode 27a that is opposite to the discharge surface is supported by the electrically insulating plate 26. The discharge electrode 27a is connected to the feedthroughs 26a. The surface of the discharge electrode 27b that is opposite to the discharge surface is supported by the ground plate 28.

The PPM 22 includes a switch 22a and the following components: a charging capacitor; a pulse transformer; a magnetism compression circuit; and a peaking capacitor, none of which is shown. The peaking capacitor is connected to the feedthroughs 26a via a connection portion that is not shown. The charger 23 charges the charging capacitor under the control of the laser processor 38.

The on/off state of the switch 22a is controlled by the laser processor 38. The laser processor 38 turns on the switch 22a in response to a light emission trigger Tr transmitted from the laser processing processor 40.

When the switch 22a is turned on, a current flows from the charging capacitor to the primary side of the pulse transformer, and the resultant electromagnetic induction causes a current in the opposite direction to flow to the secondary side of the pulse transformer. The magnetism compression circuit is connected to the secondary side of the pulse transformer and compresses the pulse width of each current pulse. The peaking capacitor is charged by the current pulses. When the voltage across the peaking capacitor reaches the breakdown voltage of the laser gas, dielectric breakdown occurs in the laser gas between the discharge electrodes 27a and 27b, resulting in the discharge. The discharge generates the laser beam Lb corresponding to one pulse.

The rear mirror 25a is formed by coating a flat substrate with a highly reflective film. The output coupling mirror 25b is formed by coating a flat substrate with a partially reflective film. The chamber 21 is disposed between the rear mirror 25a and the output coupling mirror 25b. The laser beam Lb generated in the chamber 21 is amplified by the optical resonator and output via the output coupling mirror 25b.

The monitor module 30 includes a beam splitter 31 and a photosensor 32. The beam splitter 31 is disposed in the optical path of the laser beam Lb output via the output coupling mirror 25b and reflects part of the laser beam Lb. The photosensor 32 is disposed at a position where the laser beam Lb reflected off the beam splitter 31 is incident on the photosensor 32. The photosensor 32 measures the pulse energy of the laser beam Lb and transmits the measured value to the laser processor 38.

The laser processor 38 controls the pulse energy of the laser beam Lb output from the laser apparatus 2 by changing a charging voltage applied to the charger 23 based on the value of the pulse energy measured with the photosensor 32 in such a way that the pulse energy becomes target pulse energy Et.

The shutter 35 is disposed in the optical path of the laser beam Lb having passed through the beam splitter 31. The shutter 35 opens and closes in response to an instruction from the laser processor 38. The laser processor 38 controls the output of the laser beam Lb output from the laser apparatus 2 by controlling the shutter 35.

### 1.2 Operation

The operation of the laser processing system 1 according to Comparative Example will next be described. The laser processing processor 40 first controls the XYZ stage 43 in such a way that the focal plane of the focusing lens 60 coincides with the surface 45a of the workpiece 45. The laser processing processor 40 then transmits the target pulse energy Et to the laser apparatus 2 and controls transmittance Ta of the attenuator 49 in such a way that the fluence at the surface 45a becomes target fluence Ft.

The fluence used herein is the pulse energy density per pulse of a single focused spot at the surface 45a of the workpiece 45. When the attenuator 49 has a transmittance of 100%, let T₀ be the transmittance of the optical apparatus 41, Q be the number of focused spots, and S be the area of each of the focused spots, and the target fluence Ft is expressed by Expression (1) below.

Ft=Et×Ta×T₀/(Q×S) (1)

Upon reception of the target pulse energy Et, the laser processor 38 controls the charger 23 in such a way that the pulse energy of the laser beam Lb becomes the target pulse energy Et. The laser processor 38 then inputs the trigger to the switch 22a to cause the oscillator 20 to perform spontaneous oscillation. Note that the shutter 35 is closed at this point of time.

Part of the laser beam Lb output from the chamber 21 via the output coupling mirror 25b is sampled by the monitor module 30 to measure the pulse energy of the laser beam Lb. The laser processor 38 controls the charger 23 in such a way that a difference ΔE between the pulse energy and the target pulse energy Et approaches zero. Thereafter, when the difference ΔE falls within an allowable range, the laser processor 38 transmits a permission signal to the laser processing processor 40, and opens the shutter 35.

Upon reception of the permission signal, the laser processing processor 40 transmits the light emission trigger Tr instructing a predetermined repetition frequency and a predetermined number of pulses to the laser apparatus 2. As a result, the laser beam Lb is output from the laser apparatus 2 in synchronization with the light emission trigger Tr, and enters the laser processing apparatus 4 via the optical path tube 5. The laser beam Lb is reflected off the highly reflective mirror 47a and attenuated by the attenuator 49, and then reflected off the highly reflective mirrors 47b and 47c. The laser beam Lb reflected off the highly reflective mirror 47c enters the DOE 50.

The DOE 50 divides the incident laser beam Lb into the multiple laser beams Lv at the surface 45a of the workpiece 45. The focusing lens 60 focuses each of the multiple laser beams Lv at the surface 45a of the workpiece 45 to form the multi-point pattern. The laser beams Lv each having the predetermined number of pulses are radiated to the focused spots of the multi-point pattern to cause laser ablation, so that the holes H are formed.

The laser processing processor 40 then controls the XYZ stage 43 and the laser apparatus 2 to repeatedly change irradiation positions of the multi-point pattern and perform irradiation with the laser beams by using a step-and-repeat method, so that the multiple holes H are formed across an entire processing area where the drilling is required.

### 1.3 Diffractive Optical Element

The DOE will next be described. In general, DOEs are broadly classified into dividing DOEs that divide an incident beam into multiple beams, and shaping DOEs that shape an incident beam. The DOE 50 in the present disclosure is a dividing DOE. The DOE 50 is produced by inscribing a pattern on a substrate made, for example, of quartz.

In general, it is difficult to produce a large-area DOE having a single pattern. For example, when a computer is used to generate a pattern, the size of the memory and the length of the calculation period both need to be quadrupled to double the area of the DOE. A DOE having a smaller area is therefore more readily designed and produced. Reducing the area of the DOE, however, lowers the numerical aperture of the entire optical system, resulting in a decrease in resolution. It is therefore preferable to produce a large-area DOE by tiling the DOE with multiple elements at each of which a basic pattern is formed. The decrease in resolution can thus be suppressed.

FIG. 3 shows an example of an element 51, which constitutes the DOE 50. The element 51 is a quadrangular plate at which the basic pattern is formed.

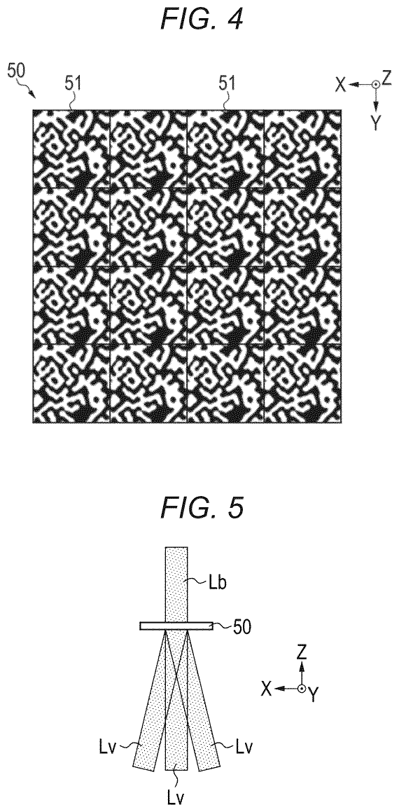

FIG. 4 shows an example of the DOE 50. The DOE 50 is formed by tiling it with multiple elements 51. That is, the DOE 50 is formed by repeatedly placing the elements 51. The basic pattern is designed so as to be continuous with the basic pattern of an adjacent element at the boundary therewith.

### 1.4 Problems

The laser apparatus 2, which is capable of an intense output and a high repetition rate, is suitable for multi-point drilling using the DOE 50. To perform drilling, the laser beam Lb of high beam quality is advantageous in terms of processing speed and processing accuracy, but the laser beam Lb, which is a multimode laser beam, has a large number of spatial modes and therefore has low beam quality. The term “multimode” refers to a state in which the number of spatial modes is two or more. The spatial mode is a mode in the directions perpendicular to the optical axis of the optical resonator, that is, a transverse mode. When the laser apparatus 2 is an excimer laser apparatus, the number of spatial modes ranges from about 10 to 1,000.

The multiple laser beams Lv, into which the laser beam Lb is divided by the DOE 50, each have the same number of spatial modes as the laser beam Lb that enters the DOE 50, and therefore each have the same beam quality as the laser beam Lb, as shown in FIG. 5. Therefore, in the laser processing system 1 according to Comparative Example, the laser beam Lb output from the laser apparatus 2 has low beam quality, which increases the diameter of each of the focused spots of the laser beams Lv focused by the focusing lens 60, resulting in a problem of decreases in processing speed and processing accuracy.

In the multi-point drilling, it is desirable to increase the number of the focused spots in order to simultaneously form a large number of holes H from a throughput perspective. In the laser processing system 1 according to Comparative Example, however, an attempt to increase the number of the focused spots presents a problem of complication of the pattern to be formed on the DOE 50, which makes it difficult to design and produce the DOE 50.

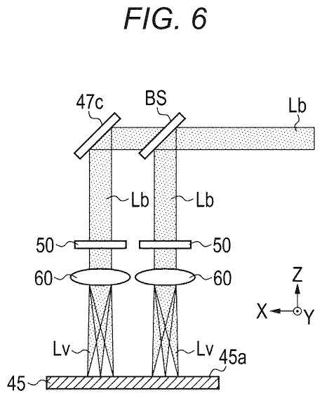

To increase the number of the focused spots, it is conceivable to divide the laser beam Lb into two laser beams Lb by using a beam splitter BS, and divide each of the two divided laser beams Lb into the multiple laser beams Lv by using the DOE 50, as shown in FIG. 6. The multiple laser beams Lv, into which the laser beam Lb is divided by each of the DOEs 50, are focused by the focusing lens 60. The number of the focused spots is thus doubled.

In the configuration shown in FIG. 6, however, the two laser beams Lb divided by the beam splitter BS each have the same number of spatial modes as the laser beam Lb incident on the beam splitter BS, and therefore have low beam quality. Therefore, even when the number of the focused spots is increased by using the beam splitter BS, the focused spots each have a large diameter, and the problem of decreases in processing speed and processing accuracy remains.

The present disclosure provides a laser processing system and an electronic device manufacturing method that allow an increase in the number of the focused spots and improvement in the processing speed and processing accuracy even when the multimode laser beam Lb is used.

### 2. First Embodiment

A laser processing system 1a according to a first embodiment of the present disclosure will be described. Note that the same configurations as those described above have the same reference characters, and duplicate description of the same configurations will be omitted unless otherwise particularly described.

### 2.1 Configuration

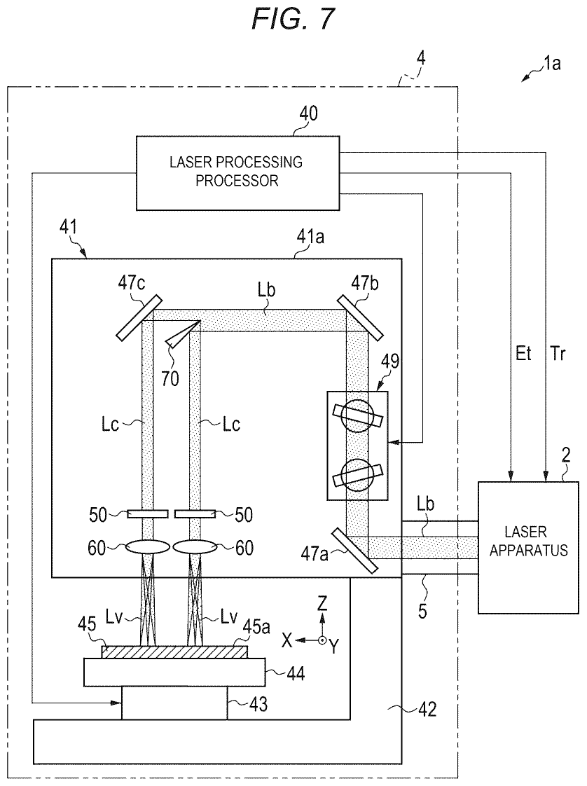

FIG. 7 schematically shows the configuration of the laser processing system 1a according to the first embodiment. The laser processing system 1a is configured in the same manner as the laser processing system 1 according to Comparative Example except for the optical apparatus 41.

In the present embodiment, in the optical apparatus 41, a wedge plate 70 is disposed in the optical path of the laser beam Lb to be incident on the highly reflective mirror 47c. For example, the wedge plate 70 is made of synthetic quartz, and has a surface coated with a highly reflective film. The wedge plate 70 reflects part of the laser beam Lb at high reflectance to split the laser beam Lb into two laser beams Lc each having the reduced number of spatial modes. It is preferable that the wedge plate 70 splits the laser beam Lb in such a way that the two laser beams Lc have the same number of spatial modes. Note in the present disclosure that “splitting” an incident laser beam means splitting the laser beam into multiple laser beams each having the reduced number of spatial modes. The wedge plate 70 is an example of the “splitting optical element” according to the technology described in the present disclosure. The laser beams Lc are an example of the “split beams” according to the technology described in the present disclosure.

It is further preferable that the wedge plate 70 is disposed so as to split the laser beam Lb in the direction corresponding to the discharge direction in the laser apparatus 2. The reason for this is that the laser beam Lb has a large number of spatial modes in the direction corresponding to the discharge direction, and therefore has low beam quality in the direction corresponding to the discharge direction. In the optical path between the highly reflective mirror 47b and the highly reflective mirror 47c, where the wedge plate 70 is disposed, the Z direction corresponds to the discharge direction.

In the present embodiment, the DOE 50 and the focusing lens 60 are disposed in the optical path of each of the two laser beams Lc, into which the laser beam Lb is split by the wedge plate 70. Specifically, the laser beam Lb is split into the laser beam Lc that has been reflected off the wedge plate 70 and the laser beam Lc that has not been reflected off the wedge plate 70 but is incident on the highly reflective mirror 47c. The DOE 50 and the focusing lens 60 are disposed in each of the optical path of the laser beam Lc reflected off the wedge plate 70 and the optical path of the laser beam Lc not reflected off the wedge plate 70 but incident on and reflected off the highly reflective mirror 47c.

The configurations of the DOE 50 and the focusing lens 60 are the same as those of the DOE 50 and the focusing lens 60 according to Comparative Example. In the present embodiment, the DOEs 50 each divide the incident laser beam Lc into the multiple laser beams Lv, which exit at different angles. The focusing lens 60 is so disposed that the multiple laser beams Lv output from the DOE 50 enter the focusing lens 60 and the focal plane thereof coincides with the surface 45a of the workpiece 45. The laser beams Lv are an example of the “divided beams” according to the technology described in the present disclosure.

The length of each of the elements 51, which constitute the DOE 50, is preferably smaller than or equal to half the length of the coherence region of the laser beam Lb.

When the number of spatial modes of the laser beam Lb is M, there are M coherence regions in the cross section of the laser beam Lb, and the coherence regions have the same area. In each of the coherence regions, the light beams are in phase and spatially coherent. Between two of the coherence regions, the light beams are out of phase and therefore spatially incoherent.

### 2.2 Operation

The laser processing system 1a according to the first embodiment operates in the same manner as the laser processing system 1 according to Comparative Example.

In the present embodiment, the laser beam Lb is split into the two laser beams Lc by the wedge plate 70, and the laser beams Lc are each divided into the multiple laser beams Lv by the DOE 50, so that the number of the focused spots formed at the surface 45a of the workpiece 45 is twice the number in Comparative Example. Therefore, in the present embodiment, the number of the simultaneously formed holes H is twice the number in Comparative Example.

### 2.3 Advantages

The two laser beams Lc, into which the laser beam Lb is split by the wedge plate 70, each have the reduced number of spatial modes, as in the case where part of the laser beam Lb is cut and extracted by using an aperture or a slit. In the present embodiment, the number of spatial modes of each of the two laser beams Lc is approximately half the number of spatial modes of the laser beam Lb. As described above, in the present embodiment, the laser beam Lc that enters the DOE 50 has the reduced number of spatial modes, so that the multiple laser beams Lv, into which the laser beam Lc is divided by the DOE 50, each also have the reduced number of spatial modes. Since the laser beams Lv, which form the focused spots, each have improved beam quality, the diameter of each of the focused spots decreases, so that the processing speed and processing accuracy are improved.

Furthermore, in the present embodiment, since the DOE 50 is disposed in the optical path of each of the two laser beams Lc, into which the laser beam Lb is split by the wedge plate 70, the same DOE 50 used in Comparative Example can be used. That is, according to the present embodiment, the number of the focused spots can be increased without producing a large-area DOE having a complex pattern. Therefore, according to the present embodiment, the number of the focused spots can be increased, and the processing speed and processing accuracy can be improved even when a multimode laser beam is used.

In the first embodiment, the laser beam Lb is split into the two laser beams Lc by the single wedge plate 70, and the laser beam Lb may instead be divided into three or more laser beams Lc by using two or more wedge plates 70. In this case, the DOE 50 and the focusing lens 60 may be disposed in the optical path of each of the split laser beams Lc. It is, however, preferable that the number of the split laser beams is smaller than or equal to the number of spatial modes of the laser beam Lb. In other words, it is preferable that the beam cross-sectional area of each of the split laser beams Lc is greater than the area of one coherence region of the laser beam Lb.

### 3. Second Embodiment

A laser processing system 1b according to a second embodiment of the present disclosure will be described. Note that the same configurations as those described above have the same reference characters, and duplicate description of the same configurations will be omitted unless otherwise particularly described.

### 3.1 Configuration

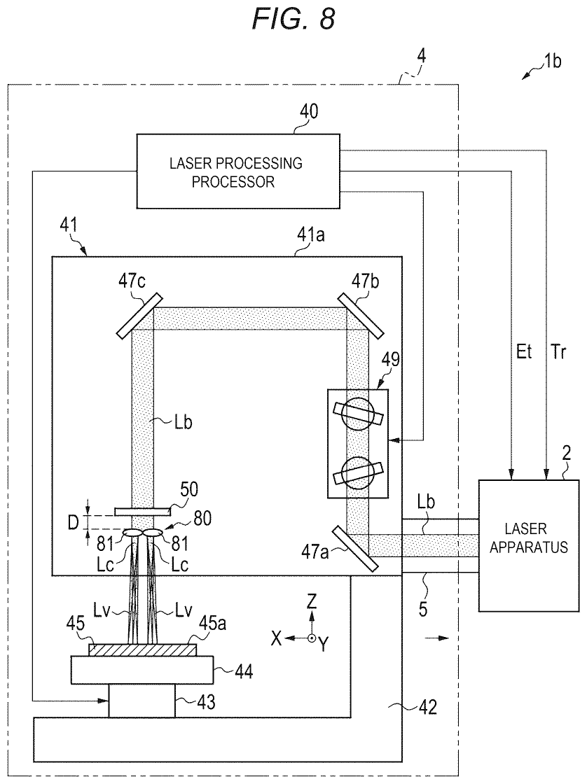

FIG. 8 schematically shows the configuration of the laser processing system 1b according to the second embodiment. The laser processing system 1b is configured in the same manner as the laser processing system 1 according to Comparative Example except for the optical apparatus 41.

The laser processing system 1b differs from the laser processing system 1 according to Comparative Example in that the focusing lens 60 is replaced with a focusing element array 80 in the optical apparatus 41. The focusing element array 80 functions as the splitting optical element.

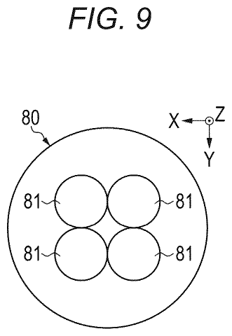

The focusing element array 80 includes multiple focusing lenses 81 that are arranged in a matrix, as shown in FIG. 9. For example, the focusing element array 80 includes two focusing lenses 81 arranged in each of the X and Y directions. Note that the number of the focusing lenses 81, which constitute the focusing element array 80, can be changed as appropriate. The focusing lenses 81 are an example of the “focusing element” according to the technology described in the present disclosure.

In the present embodiment, the focusing element array 80 is disposed downstream from the DOE 50. A distance D between the DOE 50 and the focusing element array 80 is preferably set at a structurally allowable minimum value. For example, the distance D is preferably smaller than or equal to 50 mm, more preferably, smaller than or equal to 25 mm.

The laser beam Lb having entered the DOE 50 is not yet divided immediately after output from the DOE 50, and is divided into the multiple laser beams Lv when the diffracted waves output from the DOE 50 form images at a distant location. The focusing element array 80 disposed downstream from and in the vicinity of the DOE 50 therefore has the effect of splitting the laser beam Lb into four laser beams Lc each having a reduced number of spatial modes. In the present embodiment, the focusing element array 80 splits the laser beam Lb into the four laser beams Lc.

Furthermore, the focusing lenses 81, which constitute the focusing element array 80, are disposed so as to focus the split laser beams Lc at the surface 45a of the workpiece 45. The laser beams Lc are each divided into the multiple laser beams Lv and focused at the focusing position by the effect of the DOE 50.

It is preferable that the laser beam Lb passing through the focusing lenses 81 has uniform intensity across the cross section. The reason for this is that when the intensity varies, the energy at each of the focused spots changes, which may cause variation in the processed holes H. For example, let Emax be the maximum of the intensity of the laser beam Lb passing through the multiple focusing lenses 81, which constitute the focusing element array 80, and Emin be the minimum thereof, and Expression (2) below is preferably satisfied.

(Emax−Emin)/(Emax+Emin)<0.1 (2)

Also in the present embodiment, it is preferable that the number of the laser beams into which the laser beam Lb is split by the focusing element array 80 is smaller than or equal to the number of spatial modes of the laser beam Lb. That is, it is preferable that the area of each of the focusing lenses 81 is greater than the area of one coherence region of the laser beam Lb.

### 3.2 Operation

The laser processing system 1b according to the second embodiment operates in the same manner as the laser processing system 1 according to Comparative Example.

In the present embodiment, the number of the focused spots is equal to the product of the number of the laser beams into which the original laser beam is split by the focusing element array 80 and the number of the laser beams into which the original laser beam is divided by the DOE 50. Specifically, in the present embodiment, the laser beam Lb is split into the four laser beams Lc by the focusing element array 80, and the laser beams Lc are each divided into the multiple laser beams Lv by the DOE 50, so that the number of the focused spots formed at the surface 45a of the workpiece 45 is four times the number in Comparative Example. Therefore, in the present embodiment, the number of the simultaneously formed holes His four times the number in Comparative Example.

### 3.3 Advantages

The four laser beams Lc, into which the laser beam Lb is split by the focusing element array 80, each have the reduced number of spatial modes, as in the case where part of the laser beam Lb is cut and extracted by using an aperture or a slit. In the present embodiment, the number of spatial modes of each of the four laser beams Lc is approximately one-fourth the number of spatial modes of the laser beam Lb. As described above, in the present embodiment, the laser beams Lc each have the reduced number of spatial modes, so that the multiple laser beams Lv, into which the laser beam Lc is divided by the DOE 50, each also have the reduced number of spatial modes. Since the laser beams Lv, which form the focused spots, each have improved beam quality, the diameter of each of the focused spots decreases, so that the processing speed and processing accuracy are improved.

Furthermore, in the present embodiment, the same DOE 50 as in Comparative Example can be used, so that the number of focused spots can be increased without producing a large-area DOE having a complex pattern. Therefore, according to the present embodiment, the number of the focused spots can be increased, and the processing speed and processing accuracy can be improved even when a multimode laser beam is used.

### 3.4 Simulation

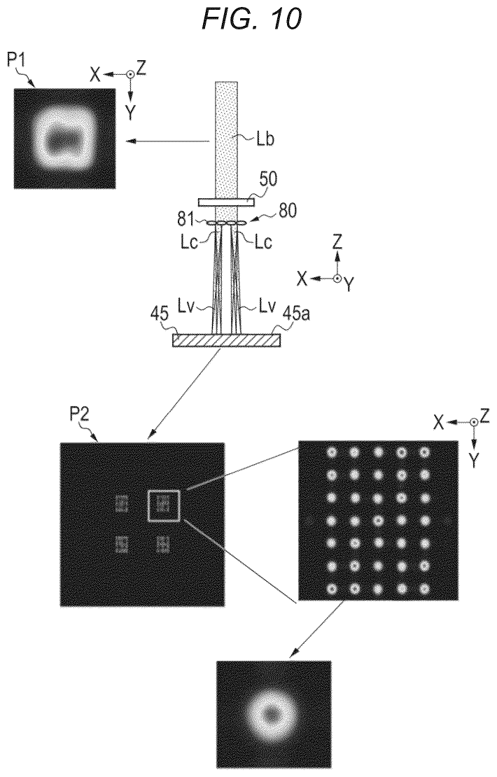

A simulation performed to ascertain the advantages of the laser processing system 1b according to the second embodiment will next be described. FIG. 10 shows a result of the simulation performed on the focused spots formed in the second embodiment.

In the present simulation, a laser beam Lb having nine spatial modes and a spatial mode distribution of 3×3 was caused to enter the DOE 50. The area of each of the elements 51, which constitute the DOE 50, is set at about 1/64 times the cross-sectional area of the incident laser beam Lb.

In the present simulation, the focusing element array 80 was formed in a 4×4 matrix in which four focusing lenses 81 are arranged in each of the X and Y directions. Note, however, that most of the laser beam Lb that enters the focusing element array 80 enters a central 2×2 region of the focusing element array 80. The number of spatial modes of the laser beam Lb passing through each of the focusing lenses 81 in the 2×2 region is approximately 2.25.

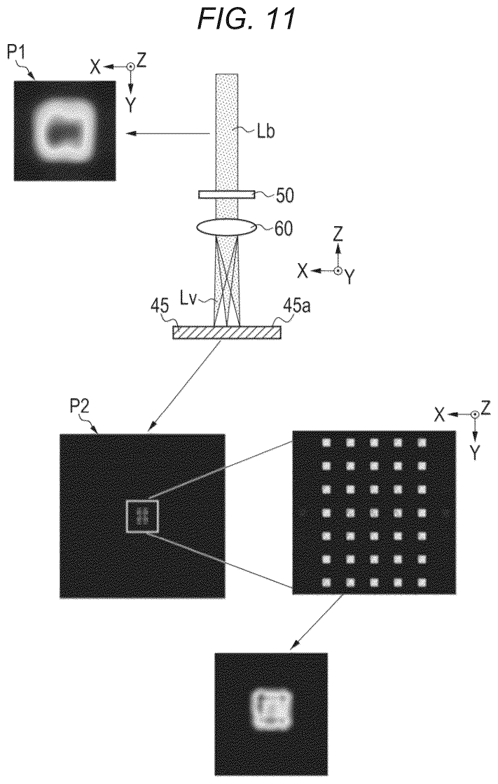

FIG. 11 shows a result of the simulation performed on the focused spots formed in Comparative Example. Also in Comparative Example, the simulation was performed under same conditions.

In FIGS. 10 and 11, reference character P1 represents the beam profile of the laser beam Lb that enters the DOE 50, and reference character P2 represents the distribution of focused spots at the surface 45a of the workpiece 45. FIGS. 10 and 11 demonstrate that the focused spots each have a quadrangular shape and have low beam quality in Comparative Example, and that the focused spots each have a circular shape and have improved beam quality in the second embodiment.

### 3.5 Variations

A variety of variations of the second embodiment will next be described.

In the second embodiment, the focusing element array 80 is disposed downstream from the DOE 50, and the focusing element array 80 may instead be disposed upstream from the DOE 50. In this case, the laser beam Lb is split by the focusing element array 80 into the four laser beams Lc, which enter the DOE 50. The DOE 50 divides each of the four laser beams Lc into the multiple laser beams Lv. Also in this case, the distance D between the DOE 50 and the focusing element array 80 is preferably set at a structurally allowable minimum value. For example, the distance D is preferably smaller than or equal to 50 mm, more preferably, smaller than or equal to 25 mm.

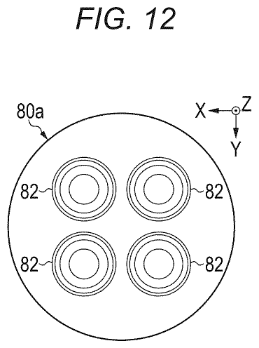

In the second embodiment, the focusing element array 80 configured with the multiple focusing lenses 81 is used, and a focusing element array 80a configured with multiple DOEs 82 may instead be used, as shown in FIG. 12. The DOEs 82 are each one type of shaping DOE, and focuses the incident laser beam Lb. The focusing element array 80a splits the incident laser beam Lb into multiple laser beams Lc each having the reduced number of spatial modes. The DOEs 82 are an example of the “focusing element” according to the technology described in the present disclosure.

### 4. Third Embodiment

A laser processing system 1c according to a third embodiment of the present disclosure will be described. Note that the same configurations as those described above have the same reference characters, and duplicate description of the same configurations will be omitted unless otherwise particularly described.

### 4.1 Configuration

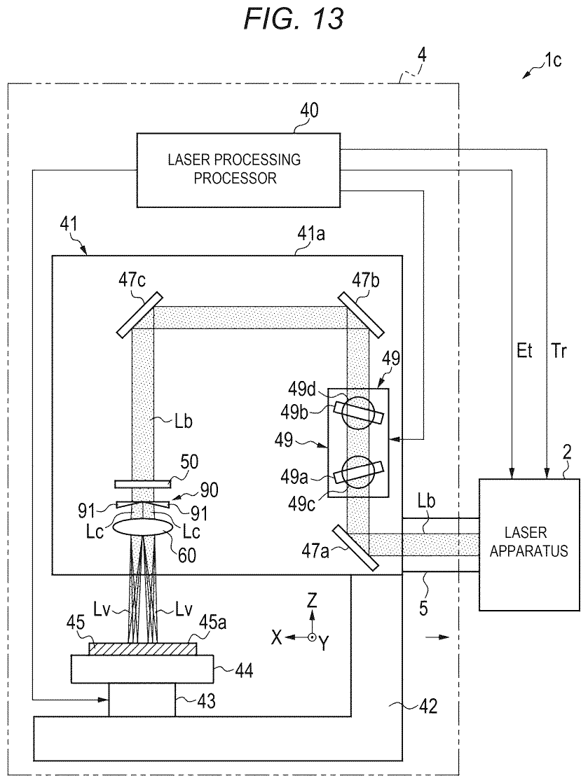

FIG. 13 schematically shows the configuration of the laser processing system 1c according to the third embodiment. The laser processing system 1c is configured in the same manner as the laser processing system 1 according to Comparative Example except for the optical apparatus 41.

The laser processing system 1c differs from the laser processing system 1 according to Comparative Example in that a deflector array 90 is provided between the DOE 50 and focusing lens 60 in the optical apparatus 41. The deflector array 90 functions as the splitting optical element.

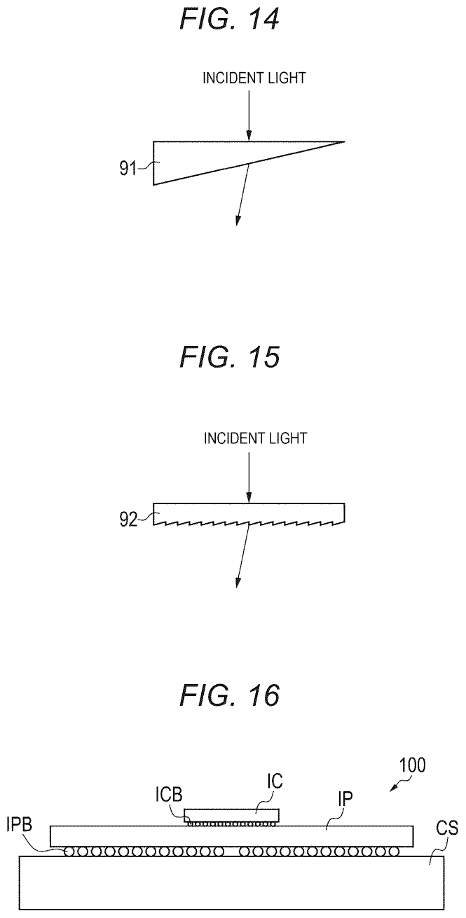

The deflector array 90 is configured with two prisms 91. The prisms 91 are each a deflector that deflects incident light and outputs the deflected light, as shown in FIG. 14. The two prisms 91 are so arranged that the deflection directions thereof differ from each other. The prisms 91 are an example of the “deflector” according to the technology described in the present disclosure.

In the present embodiment, the deflector array 90 is disposed downstream from the DOE 50. The distance between the DOE 50 and the deflector array 90 is preferably set at a structurally allowable minimum value. In the present embodiment, the focusing lens 60 is disposed downstream from the deflector array 90. The distance between the deflector array 90 and the focusing lens 60 is preferably set at a structurally allowable minimum value.

The laser beam Lb having entered the DOE 50 is not yet divided immediately after output from the DOE 50, and is divided into the multiple laser beams Lv when the diffracted waves output from the DOE 50 form images at a distant location. The deflector array 90 disposed downstream from and in the vicinity of the DOE 50 therefore has the effect of splitting the laser beam Lb into two laser beams Lc deflected in directions different from each other and each having the reduced number of spatial modes.

The focusing lens 60 is disposed so as to focus the split laser beams Lc from the deflector array 90 at the surface 45a of the workpiece 45. Furthermore, since the laser beams Lc that enter the focusing lens 60 travel in different directions, the focusing lens 60 focuses the laser beams Lc at different positions on the surface 45a. The laser beams Lc are each divided into the multiple laser beams Lv and focused at the focusing position by the effect of the DOE 50.

### 4.2 Operation

The laser processing system 1c according to the third embodiment operates in the same manner as the laser processing system 1 according to Comparative Example.

In the present embodiment, the number of the focused spots is equal to the product of the number of the laser beams into which the original laser beam is split by the deflector array 90 and the number of the laser beams into which the original laser beam is divided by the DOE 50. Specifically, in the present embodiment, the laser beam Lb is split into the two laser beams Lc by the deflector array 90, and the laser beams Lc are each divided into the multiple laser beams Lv by the DOE 50, so that the number of the focused spots formed at the surface 45a of the workpiece 45 is twice the number in Comparative Example. Therefore, in the present embodiment, the number of the simultaneously formed holes H is twice the number in Comparative Example.

### 4.3 Advantages

The two laser beams Lc, into which the laser beam Lb is split by the deflector array 90, each have the reduced number of spatial modes, as in the case where part of the laser beam Lb is cut and extracted by using an aperture or a slit. In the present embodiment, the number of spatial modes of each of the two laser beams Lc is approximately half the number of spatial modes of the laser beam Lb. As described above, in the present embodiment, the laser beams Lc each have the reduced number of spatial modes, so that the multiple laser beams Lv, into which the laser beam Lc is divided by the DOE 50, each also have the reduced number of spatial modes. Since the laser beams Lv, which form the focused spots, each have improved beam quality, the diameter of each of the focused spots decreases, so that the processing speed and processing accuracy are improved.

Furthermore, in the present embodiment, the same DOE 50 as in Comparative Example can be used, so that the number of focused spots can be increased without producing a large-area DOE having a complex pattern. Therefore, according to the present embodiment, the number of the focused spots can be increased, and the processing speed and processing accuracy can be improved even when a multimode laser beam is used.

Note in the third embodiment that the deflector array 90 is disposed downstream from the DOE 50, and the deflector array 90 may instead be disposed upstream from the DOE 50. In this case, the laser beam Lb is split by the deflector array 90 into two laser beams Lc, which enter the DOE 50. The DOE 50 divides each of the two laser beams Lc into the multiple laser beams Lv. Also in this case, the distance between the DOE 50 and the deflector array 90 is preferably set at a structurally allowable minimum value.

In the third embodiment, the laser beam Lb is split into the two laser beams Lc by the two prisms 91, which constitute the deflector array 90, and the laser beam Lb may instead be split into three or more laser beams Lc by using three or more prisms 91.

Furthermore, in the third embodiment, the deflector array 90 is configured with the multiple prisms 91 in the form of an array, and may instead be configured with DOEs 92 in the form of an array, as shown in FIG. 15. The DOEs 92 are an example of the “deflector” according to the technology described in the present disclosure.

### 5. Electronic Device Manufacturing Method

The laser processing method according to each of the embodiments described above is applicable to formation of through holes in a substrate that forms an interposer IP in the manufacture of electronic devices 100 described below.

FIG. 16 diagrammatically shows the configuration of each of the electronic devices 100. The electronic device 100 shown in FIG. 16 includes an integrated circuit chip IC, the interposer IP, and a circuit substrate CS. The integrated circuit chip IC is, for example, a chip in which an integrated circuit that is not shown is formed in a silicon substrate. The integrated circuit chip IC is provided with multiple bumps ICB electrically connected to the integrated circuit.

The interposer IP includes an insulating substrate having multiple through holes that are not shown but are formed therein, and an electrical conductor that is not shown but electrically connects the front and rear sides of the substrate to each other is provided in each of the through holes. Multiple lands that are not shown but are connected to the bumps ICB are formed at one surface of the interposer IP, and the lands are each electrically connected to one of the electrical conductors in the through holes. Multiple bumps IPB are provided at the other surface of the interposer IP, and the bumps IPB are each electrically connected to one of the electrical conductors in the through holes.

Multiple lands that are not shown but are connected to the respective bumps IPB are formed at one surface of the circuit substrate CS. The circuit substrate CS includes multiple terminals to be electrically connected to the lands.

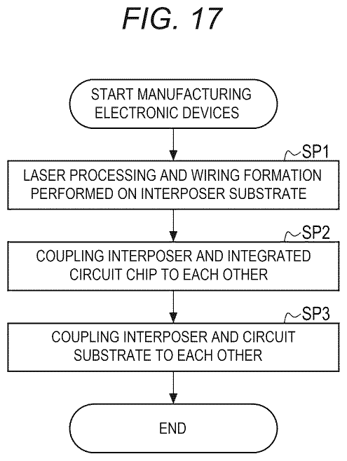

FIG. 17 shows a method for manufacturing the electronic devices 100. First, in first step SP1, laser processing and wiring formation are performed on an interposer substrate that constitutes the interposer IP. The laser processing performed on the interposer substrate includes forming through holes by irradiating the interposer substrate with a pulse laser beam. The wiring formation includes formation of an electrically conductive film at the inner wall surface of each of the through holes formed in the interposer substrate. In first step SP1, the interposer IP is produced.

Thereafter, in second step SP2, the interposer IP and the integrated circuit chip IC are coupled to each other. Second step SP2 includes, for example, placing the bumps ICB of the integrated circuit chip IC on the lands of the interposer IP, and electrically connecting the bumps ICB and the lands to each other.

Thereafter, in third step SP3, the interposer IP and the circuit substrate CS are coupled to each other. Third step SP3 includes, for example, placing the bumps IPB of the interposer IP on the lands of the circuit substrate CS, and electrically connecting the bumps IPB and the lands to each other.

The above description is intended not to be limiting but merely to be illustrative. It will therefore be apparent for a person skilled in the art that the embodiments of the present disclosure can be changed without departing from the accompanying claims.

The terms used throughout the present specification and the appended claims should be interpreted as non-limiting terms. For example, the term “include” or “included” should be interpreted as “is not limited to what is described as included”. The term “have” should be interpreted as “is not limited to what is described as having”. Furthermore, indefinite articles “a/an” described in the present specification and the appended claims should be interpreted to mean “at least one” or “one or more”. Moreover, “at least one of A, B, and C” should be interpreted to mean any of “A”, “B”, “C”, “A+B”, “A+C”, “B+C”, and “A+B+C” as well as to include combinations of any of those described above and any other than “A”, “B”, and “C”.

What is claimed is:

1. A laser processing system comprising:
a laser apparatus configured to output a laser beam having two or more spatial modes;
a splitting optical element disposed in an optical path of the laser beam and configured to split the laser beam into multiple split beams each having the spatial modes with the number thereof reduced; and
at least one dividing diffractive optical element configured to divide each of the multiple split beams into multiple divided beams at a surface of a workpiece.

2. The laser processing system according to claim 1, wherein
the dividing diffractive optical element is formed by repeatedly placing an element at which a basic pattern is formed.

3. The laser processing system according to claim 2, wherein
a length of the element is smaller than or equal to half a length of one coherence region of the laser beam.

4. The laser processing system according to claim 1, wherein
the splitting optical element is a wedge plate configured to reflect part of the laser beam at high reflectance.

5. The laser processing system according to claim 4, wherein
the dividing diffractive optical element is disposed in an optical path of each of the multiple split beams.

6. The laser processing system according to claim 5, further comprising
a focusing lens disposed downstream from the dividing diffractive optical element and configured to focus the multiple divided beams at the surface of the workpiece.

7. The laser processing system according to claim 1, wherein
the splitting optical element is a focusing element array configured with multiple focusing elements, and is disposed downstream or upstream from the dividing diffractive optical element.

8. The laser processing system according to claim 7, wherein
the focusing elements are each a focusing lens or a diffractive optical element.

9. The laser processing system according to claim 7, wherein
a distance between the splitting optical element and the dividing diffractive optical element is 50 mm or smaller.

10. The laser processing system according to claim 7, wherein
an area of each of the focusing elements is greater than an area of one coherence region of the laser beam.

11. The laser processing system according to claim 7, wherein
(Emax−Emin)/(Emax+Emin)<0.1 is satisfied, where Emax represents a maximum of intensity of the laser beam passing through the multiple focusing elements, and Emin represents a minimum thereof.

12. The laser processing system according to claim 1, wherein
the splitting optical element is a deflector array configured with multiple deflectors, and is disposed downstream or upstream from the dividing diffractive optical element.

13. The laser processing system according to claim 12, wherein
the deflectors are each a prism or a diffractive optical element.

14. The laser processing system according to claim 1, wherein
the number of the split beams into which the laser beam is split by the splitting optical element is smaller than or equal to the number of the spatial modes of the laser beam.

15. An electronic device manufacturing method comprising:
producing an interposer by performing laser processing on an interposer substrate by using a laser processing system;
coupling the interposer and an integrated circuit chip to each other to electrically connect the interposer and the integrated circuit chip to each other; and
coupling the interposer and a circuit substrate to each other to electrically connect the interposer and the circuit substrate to each other,
the laser processing system including
a laser apparatus configured to output a laser beam having two or more spatial modes,
a splitting optical element disposed in an optical path of the laser beam and configured to split the laser beam into multiple split beams each having the spatial modes with the number thereof reduced, and
at least one dividing diffractive optical element configured to divide each of the multiple split beams into multiple divided beams at a surface of a workpiece.
